(19) United States
(12) Patent Application Publication
(10) Pub. No.: US 2018/0040353 A1
(43) Pub. Date: Feb. 8, 2018

(54) SEMICONDUCTOR MEMORY DEVICE AND METHOD OF OPERATING THE SAME

(71) Applicant: SK hynix Inc., Icheon-si Gyeonggi-do (KR)

(72) Inventor: Hee Youl LEE, Icheon-si Gyeonggi-do (KR)

(73) Assignee: SK hynix Inc., Icheon-si Gyeonggi-do (KR)

(21) Appl. No.: 15/494,003

(22) Filed: Apr. 21, 2017

(30) Foreign Application Priority Data
Aug. 8, 2016 (KR) 1020160100788

(51) Int. Cl. G11C 7/10; G11C 5/14; G11C 11/56; G11C 8/10

(52) U.S. Cl. CPC G11C 7/10; G11C 8/10; G11C 5/147; G11C 11/56

(57) ABSTRACT

Provided herein may be a semiconductor memory device. The semiconductor memory device may include a memory cell array, a peripheral circuit, and a control logic. The memory cell array may include a plurality of memory cells each of which is configured to store two or more bits of data. The peripheral circuit may be configured to read the data stored in the plurality of memory cells. The control logic may be configured to control the peripheral circuit to perform a read operation for the memory cell array. The control logic may selectively determine a second page read voltage for reading second page data of the selected memory cells, based on the result of reading the first page data.

### CROSS-REFERENCE TO RELATED APPLICATION

The present application claims priority under 35 U.S.C. §119(a) to Korean patent application number 10-2016-0100788 filed on Aug. 8, 2016 in the Korean Intellectual Property Office, the entire disclosure of which is incorporated herein by reference.

### BACKGROUND

### 1. Technical Field

Various embodiments of the present disclosure may generally relate to a semiconductor memory device and a method of operating the same, and more particularly, to a semiconductor memory device regarding multi-level cells, and a method of operating the same.

### 2. Related Art

Semiconductor memory devices are memory devices realized using a semiconductor material such as silicon (Si), germanium (Ge), gallium arsenide (GaAs), indium phosphide (InP), or the like. Semiconductor memory devices are classified into volatile memory devices and nonvolatile memory devices.

The volatile memory device is a memory device in which data stored therein is lost when power is turned off. Representative examples of the volatile memory device include a static RAM (SRAM), a dynamic RAM (DRAM), a synchronous DRAM (SDRAM), etc. The nonvolatile memory device is a memory device in which data stored therein is maintained even when power is turned off. Representative examples of the nonvolatile memory device include a read-only memory (ROM), a programmable ROM (PROM), an electrically programmable ROM (EPROM), an electrically erasable programmable ROM (EEPROM), a flash memory, a phase-change random access memory (PRAM), a magnetic RAM (MRAM), a resistive RAM (RRAM), a ferroelectric RAM (FRAM), etc. The flash memory is classified into a NOR type memory and a NAND type memory.

### SUMMARY

In an embodiment of the present disclosure, a semiconductor memory device may be provided. A semiconductor memory device may include a memory cell array, a peripheral circuit, and a control logic. The memory cell array may include a plurality of memory cells each of which is configured to store two or more bits of data. The peripheral circuit may be configured to read the data stored in the plurality of memory cells. The control logic may be configured to control the peripheral circuit to perform a read operation for the memory cell array. The control logic may selectively determine a second page read voltage for reading second page data of the selected memory cells, based on the result of reading the first page data.

In an embodiment of the present disclosure, a method of operating a semiconductor memory device may be provided. The method may include a plurality of memory cells each of which is configured to store two or more bits of data, the method may include reading first page data of selected memory cells. The method may include reading second to N-th page data based on the read first page data. N may be an integer greater than or equal to 2.

According to an embodiment of the present disclosure, a method of operating a semiconductor memory device may be provided. The method may include a plurality of memory cells each of which is configured to store two or more bits of data, the method may include reading, using a first read voltage, first page data of selected memory cells among the plurality of memory cells. The method may include selectively determining a second page read voltage for reading second page data of the selected memory cells, based on a read result of the first page data. The method may include reading the second page data of the selected memory cells, based on the determined second page read voltage.

### BRIEF DESCRIPTION OF THE DRAWINGS

FIG. 1 is a block diagram illustrating a semiconductor memory device in accordance with an embodiment of the present disclosure.

FIG. 2 is a flowchart illustrating a method of operating the semiconductor memory device in accordance with an embodiment of the present disclosure.

FIG. 3 is a flowchart illustrating a process of performing an operation of reading a first page in the operation method illustrated in FIG. 2;

FIG. 4 is a flowchart illustrating a process of performing an operation of reading second to N-th pages in the operation method illustrated in FIG. 2;

FIG. 5 is a diagram illustrating threshold voltage states of memory cells and read voltages corresponding thereto, for each of the memory cells that store 3-bit data.

FIG. 6 is a diagram illustrating threshold voltage states of memory cells and read voltages corresponding thereto, for each of the memory cells that store 4-bit data.

FIG. 7 is a block diagram illustrating a memory system including the semiconductor memory device of FIG. 1.

FIG. 8 is a block diagram illustrating an example of application of the memory system of FIG. 7.

FIG. 9 is a block diagram illustrating a computing system including the memory system illustrated with reference to FIG. 8.

### DETAILED DESCRIPTION

Hereinafter, embodiments will be described in with reference to the accompanying drawings. Embodiments are described herein with reference to cross-sectional illustrations that are schematic illustrations of embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements.

Terms such as ‘first’ and ‘second’ may be used to describe various components, but they should not limit the various components. Those terms are only used for the purpose of differentiating a component from other components. For example, a first component may be referred to as a second component, and a second component may be referred to as a first component and so forth without departing from the spirit and scope of the present disclosure. Furthermore, ‘and/or’ may include any one of or a combination of the components mentioned.

Furthermore, a singular form may include a plural from as long as it is not specifically mentioned in a sentence. Furthermore, “include/comprise” or “including/comprising” used in the specification represents that one or more components, steps, operations, and elements exist or are added.

Furthermore, unless defined otherwise, all the terms used in this specification including technical and scientific terms have the same meanings as would be generally understood by those skilled in the related art. The terms defined in generally used dictionaries should be construed as having the same meanings as would be construed in the context of the related art, and unless clearly defined otherwise in this specification, should not be construed as having idealistic or overly formal meanings.

It is also noted that in this specification, “connected/coupled” refers to one component not only directly coupling another component but also indirectly coupling another component through an intermediate component. On the other hand, “directly connected/directly coupled” refers to one component directly coupling another component without an intermediate component.

Examples of embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the examples of embodiments to those skilled in the art.

In the drawing figures, dimensions may be exaggerated for clarity of illustration. It will be understood that when an element is referred to as being “between” two elements, it can be the only element between the two elements, or one or more intervening elements may also be present.

Various embodiments of the present disclosure may be directed to a semiconductor memory device which may perform a read operation at an enhanced speed.

Various embodiments of the present disclosure may be directed to a read operation method of a semiconductor memory device with an enhanced speed.

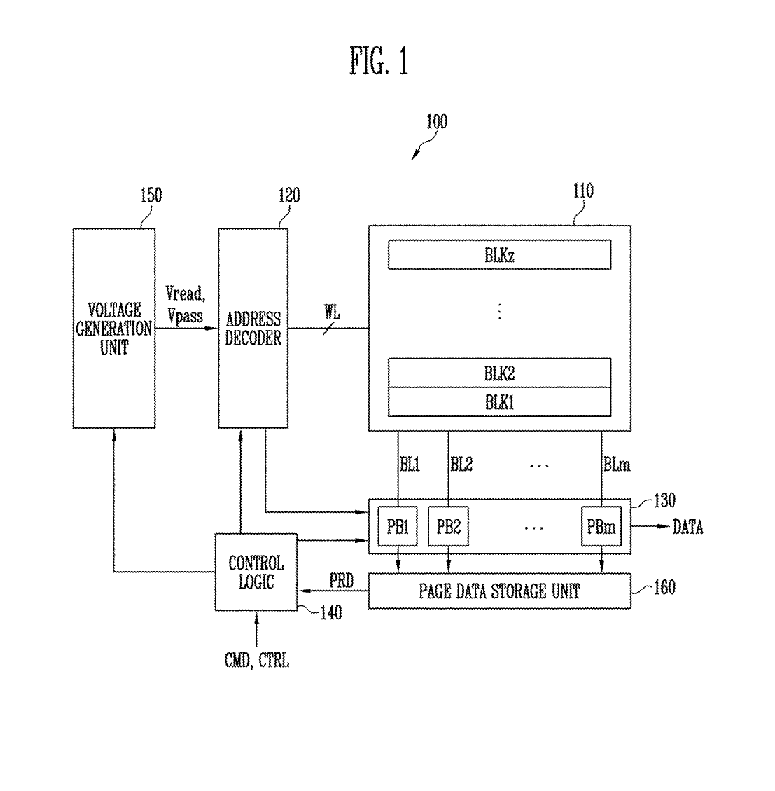

FIG. 1 is a block diagram illustrating a semiconductor memory device in accordance with an embodiment of the present disclosure.

Referring to FIG. 1, a semiconductor memory device 100 includes a memory cell array 110, an address decoder 120, a read/write circuit 130, a control logic 140, a voltage generation unit 150, and a page data storage unit 160.

The memory cell array 110 includes a plurality of memory blocks BLK1 to BLKz. The memory blocks BLK1 to BLKz are coupled to the address decoder 120 through word lines WL. The memory blocks BLK1 to BLKz are coupled to the read/write circuit 130 through bit lines BL1 to BLm. Each of the memory blocks BLK1 to BLKz includes a plurality of memory cells. In an embodiment, the plurality of memory cells may be nonvolatile memory cells and be configured with nonvolatile memory cells having a vertical channel structure. The memory cell array 110 may be formed of a memory cell array having a two-dimensional structure. In various embodiments, the memory cell array 110 may be formed of a memory cell array having a three-dimensional structure. In an embodiment of the present disclosure, each of the plurality of memory cells included in the memory cell array 110 may store at least two bits of data. In an embodiment, each of the memory cells included in the memory cell array 110 may be a multi-level cell (MLC), which stores two bits of data. In an embodiment, each of the memory cells included in the memory cell array 110 may be a triple-level cell, which stores three bits of data. In an embodiment, each of the memory cells included in the memory cell array 110 may be a quad-level cell, which stores four bits of data. In various embodiments, the memory cell array 110 may include a plurality of memory cells each of which stores five or more bits of data. In an embodiment, the memory cell array 110 may include at least one kind of memory cells among MLCs, TLCs and QLCs.

The address decoder 120, the read and write circuit 130, and voltage generation unit 150 function as a peripheral circuit for driving the memory cell array 110. The peripheral circuit performs operations for writing data to the memory cell array 110, reading data from the memory cell array 110, or erasing data of the memory cell array. The peripheral circuit is controlled by the control logic 140 to perform the write operation, the read operation or the erase operation. The address decoder 120 is coupled to the memory cell array 110 through the word lines WL. The address decoder 120 is configured to operate in response to control of the control logic 140. The address decoder 120 may receive addresses through an input/output buffer (not illustrated) provided in the semiconductor memory device 100.

The address decoder 120 is configured to decode a block address among the received addresses. The address decoder 120 may select at least one memory block in response to the decoded block address. When a read voltage application operation is performed during a read operation, the address decoder 120 may apply a read voltage Vread generated from the voltage generation unit 150, to a selected word line of a selected memory block, and apply a pass voltage Vpass to the other unselected word lines. During a program verify operation, the address decoder 120 may apply a verify voltage generated from the voltage generation unit 150, to a selected word line of a selected memory block, and apply a pass voltage Vpass to the other unselected word lines.

The address decoder 120 is configured to decode a column address among the received addresses. The address decoder 120 may transmit the decoded column address to the read/write circuit 130.

The read or program operation of the semiconductor memory device 100 is performed on a page basis. Addresses received in a request for a read or program operation may include a block address, a row address and a column address. The address decoder 120 selects one memory block and one word line in accordance with a block address and a row address. The column address is decoded by the address decoder 120 and provided to the read/write circuit 130.

The address decoder 120 may include a block decoder, a row decoder, a column decoder, an address buffer, etc.

The read and write (read/write) circuit 130 includes a plurality of page buffers PB1 to PBm. The read/write circuit 130 may be operated as a read circuit during a read operation of the memory cell array 110 and as a write circuit during a write operation. The plurality of page buffers PB1 to PBm are coupled to the memory cell array 110 through the bit lines BL1 to BLm. During a read or program operation, to sense threshold voltages of the memory cells, the page buffers PB1 to PBm may continuously supply sensing current to the bit lines coupled to the memory cells, and each page buffer may sense, through a sensing node, a change in the amount of flowing current depending on a program state of a corresponding memory cell and latch it as sensing data. The read/write circuit 130 is operated in response to page buffer control signals outputted from the control logic 140.

During a read operation, the read/write circuit 130 may sense data of the memory cells and temporarily store read-out data, and then output data DATA to the input/output buffer (not illustrated) of the semiconductor memory device 100. In an embodiment, the read/write circuit 130 may include a column select circuit or the like as well as the page buffers (or page resistors).

The control logic 140 is coupled to the address decoder 120, the read/write circuit 130, and the voltage generation unit 150. The control logic 140 may receive a command CMD and a control signal CTRL through the input/output buffer (not illustrated) of the semiconductor memory device 100. The control logic 140 is configured to control the overall operation of the semiconductor memory device 100 in response to the control signal CTRL. The control logic 140 may output a control signal for controlling the sensing node precharge potential levels of the plurality of page buffers PB1 to PBm. The control logic 140 may control the read/write circuit 130 to perform a read operation of the memory cell array 110.

The voltage generation unit 150 generates a read voltage Vread and a pass voltage Vpass during a read operation in response to a voltage generation unit control signal outputted from the control logic 140.

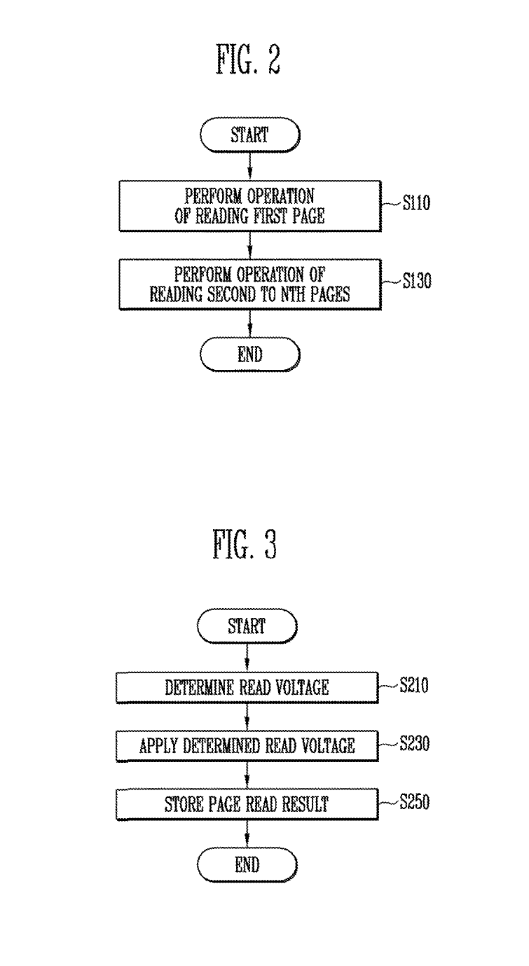

The page data storage unit 160 receives read result data for a first page of memory cells selected in the memory cell array 110 from a read/write circuit 130 and stores the read result data. During a read operation, a word line to be a target of the read operation is determined. Memory cells coupled to the determined word line are selected memory cells. Data of a first page of the associated memory cells are stored in the page data storage unit 160. The page read result data PRD stored in the page data storage unit 160 is transmitted to the control logic 140. The control logic 140 may selectively determine, based on the received page read result data PRD, read voltages to be used when a second page of the selected memory cells is read. A process of selectively determining, by the control logic 140, based on the received page read result data PRD, read voltages to be used when the second page of the selected memory cells is read will be described later herein with reference to FIGS. 2 to 6. Although the page data storage unit 160 has been illustrated in FIG. 1 as being configured separately from the control logic 140, the page data storage unit 160 may be integrally provided in the control logic 140 in some embodiments.

In the case where each of the memory cells in the memory cell array 110 is an MLC, which stores 2-bit data, the page data storage unit 160 may store read result data for a first page of selected memory cells. In an embodiment, in the case where each of the memory cells in the memory cell array 110 is a TLC, which stores 3-bit data, the page data storage unit 160 may store not only read result data for a first page of selected memory cells but also read result data for a second page thereof. The read result data for the second page is also transmitted to the control logic 140. Based on the received read result data for the second page, the control logic 140 selectively determine read voltages to be used when a third page of the selected memory cells is read. A process of selectively determining, by the control logic 140, based on the received page read result data PRD, read voltages to be used when the third page of the selected memory cells is read will be described later herein with reference to FIGS. 2 to 6.

In an embodiment, in the case where each of the memory cells in the memory cell array 110 is a QLC, which stores 4-bit data, the page data storage unit 160 may store not only read result data for first and second pages of selected memory cells but also read result data for a third page thereof. The read result data for the third page is also transmitted to the control logic 140. Based on the received read result data for the third page, the control logic 140 selectively determine read voltages to be used when a fourth page of the selected memory cells is read. A process of selectively determining, by the control logic 140, based on the received page read result data PRD, read voltages to be used when the fourth page of the selected memory cells is read will be described later herein with reference to FIGS. 2 to 6.

FIG. 2 is a flowchart illustrating a method of operating the semiconductor memory device in accordance with an embodiment of the present disclosure. Referring to FIG. 2, there is illustrated an operation of reading selected memory cells in the method of operating the semiconductor memory device in accordance with an embodiment of the present disclosure. Memory cells coupled to word lines selected for a read operation are selected memory cells, and two- or more-bit data stored in the corresponding memory cells may be read through the read operation illustrated in FIG. 2.

Referring to FIG. 2, the method of operating the semiconductor memory device in accordance with an embodiment includes step S110 of performing an operation of reading a first page, and step S130 of performing an operation of reading second to N-th pages based on the read first page data.

In the case where each of the selected memory cells in the memory cell array 110 is an MLC, which stores 2-bit data, the value of ‘N’ is 2, and at step S130, an operation of reading a second page is performed, based on the first page data read at step S110. In the case where each of the selected memory cells in the memory cell array 110 is a TLC, which stores 3-bit data, the value of ‘N’ is 3, and at step S130, an operation of reading a second page and an operation of reading a third page are performed, based on the first page data read at step S110. In the case where each of the selected memory cells in the memory cell array 110 is a QLC, which stores 4-bit data, the value of ‘N’ is 4, and at step S130, an operation of reading a second page, an operation of reading a third page and an operation of reading a fourth page are performed, based on the first page data read at step S110.

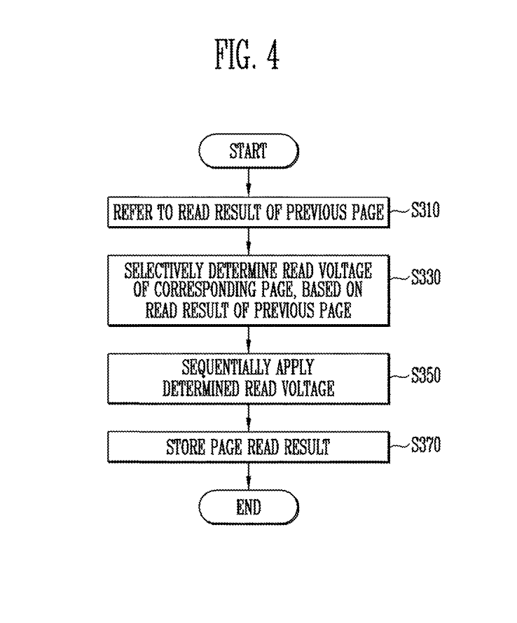

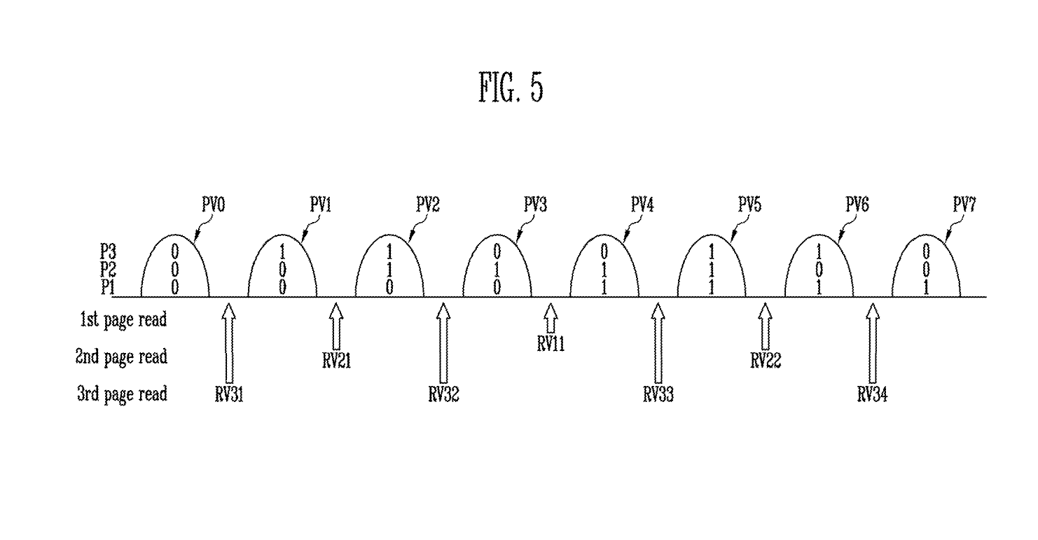

With regard to the method of operating the semiconductor memory device illustrated in FIG. 2, a process of step S110 of performing a read operation for a first page will be described later herein with reference to FIG. 3. With regard to the method of operating the semiconductor memory device illustrated in FIG. 2, a process of step S130 of performing a read operation for second to N-th pages will be described later herein with reference to FIG. 4.

FIG. 3 is a flowchart illustrating a process of performing the operation of reading the first page in the operation method illustrated in FIG. 2.

Referring to FIG. 3, step S110 of performing the operation of reading the first page illustrated in FIG. 2 includes step S210 of determining a read voltage for reading the first page, step S230 of applying the determined read voltage to word lines of selected memory cells and reading first page data of the selected memory cells, and step S250 of storing page read result data PRD of the read first page.

At step S210 of determining a read voltage for reading the first page, the read voltage to be applied when the first page of the selected memory cells is read is determined. The read voltage for reading the first page may be defined as a first read voltage. The first read voltage may be predetermined, and generated from the voltage generation unit 150 in the semiconductor memory device 100 illustrated in FIG. 1. As described below, for all of the MLC, TLC and QLC, the read voltage for reading the first page may be, for example but not limited to, a single voltage that is predetermined.

At step S230 of applying the determined read voltage to word lines of selected memory cells and reading first page data of the selected memory cells, the first read voltage is applied to the word lines coupled with the selected memory cells. Referring to FIG. 3 along with FIG. 1, first page data stored in the selected memory cells in the memory cell array 110 are transmitted to the respective page buffers PB1, . . . , PBm in the read/write circuit 130 through the corresponding bit lines BL1, . . . , BLm. That is, at step S230, first page data of an ‘m’ number of selected memory cells is read by the page buffers PB1, . . . , PBm in the read/write circuit 130.

At step S250 of storing page read result data PRD of the read first page, read result data of the first page read by the page buffers PB1, . . . , PBm is stored in the page data storage unit 160. The page read result data PRD of the first page that is stored in the page data storage unit 160 is used when a read voltage for reading second page data is determined. For this, as described below, the page read result data PRD of the first page may be transmitted to the control logic 140.

FIG. 4 is a flowchart illustrating a process of performing an operation of reading second to N-th pages in the operation method illustrated in FIG. 2.

Referring to FIG. 4, at step S130 of performing the operation of reading the second to N-th pages illustrated in FIG. 2, an operation of reading each page includes the step S310 of referring to a read result of a previous page of the selected memory cells, step S330 of selectively determining a read voltage of a corresponding page based on the read result of the previous page, step S350 of sequentially applying the determined read voltage, and step S370 of storing a read result of the corresponding page. Steps S310 to S370 illustrated in FIG. 4 may be repeatedly performed for the operation of reading the second to N-th pages. For example, in the case where each of the selected memory cells is an MLC, which stores 2-bit data, steps S310 to S370 illustrated in FIG. 2 may be performed once for the operation of reading the second page. In an embodiment, in the case where each of the selected memory cells is a TLC, which stores 3-bit data, steps S310 to S370 illustrated in FIG. 4 may be performed two times for the operation of reading the second and third pages. In an embodiment, in the case where each of the selected memory cells is a QLC, which stores 4-bit data, steps S310 to S370 illustrated in FIG. 4 may be performed three times for the operation of reading the second and fourth pages.

At step S310 of referring to the read result of the previous page of the selected memory cells, immediately previously stored page data is referred to. For example, in the case where the operation of reading a second page of selected memory cells is performed by steps S310 to S370 illustrated in FIG. 4, first page data of the selected memory cells is referred to, at step S310. Step S310 may be performed by the control logic 140, and the control logic 140 may refer to the first page data in the page read result data PRD stored in the page data storage unit 160. In an embodiment, in the case where the operation of reading a third page of selected memory cells is performed by steps S310 to S370 illustrated in FIG. 4, second page data of the selected memory cells is referred to, at step S310. Likewise, in the case where the operation of reading a fourth page of selected memory cells is performed by steps S310 to S370 illustrated in FIG. 4, third page data of the selected memory cells is referred to, at step S310.

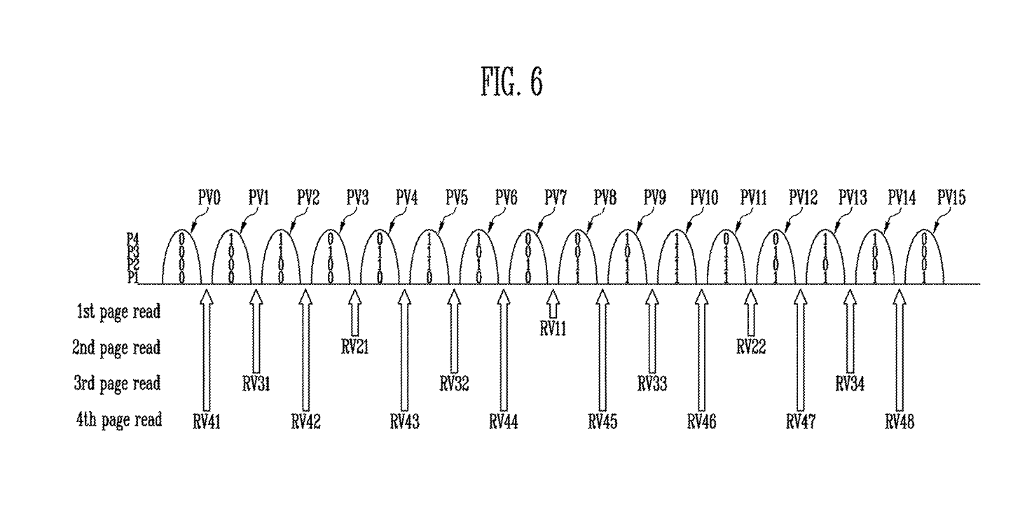

At step S330 of selectively determining the read voltage of the corresponding page based on the read result of the previous page, at least one read voltage to be used for an operation of reading the corresponding page is selected. The number of read voltages to be selected at step S330 may be determined based on the read result of the previous page. For example, in the case where the operation of reading a second page of selected memory cells is performed by steps S310 to S370 illustrated in FIG. 4, one or two read voltages may be selected, at step S330. In an other example, in the case where the operation of reading a third page of selected memory cells is performed by steps S310 to S370 illustrated in FIG. 4, one to four read voltages may be selected, at step S330. In still another example, in the case where the operation of reading a fourth page of selected memory cells is performed by steps S310 to S370 illustrated in FIG. 4, one to eight read voltages may be selected, at step S330. Step S330 may be performed by the control logic 140. A process of selecting a read voltage based on a read result of a previous page for an operation of reading each page will be described later herein with reference to FIGS. 5 and 6.

At step S350 of applying sequentially applying the determined read voltage and step S370 of storing the read result of the corresponding page, at least one or more read voltages determined at step S330 are sequentially applied to the selected word lines to read data of the corresponding page of the selected memory cells. According to the method of operating the semiconductor memory device in accordance with an embodiment of the present disclosure, the number of read voltages needed during a read operation may be reduced based on data of a previous page. Therefore, the time required for the read operation of the semiconductor memory device may be reduced.

FIG. 5 is a diagram illustrating threshold voltage states of memory cells and read voltages corresponding thereto, for each of the memory cells that stores 3-bit data. Hereinafter, a read operation of a semiconductor memory device including TLCs will be described with reference to FIGS. 2 to 5.

Referring to FIG. 5, there are illustrated program states of TLCs and values of 3-bit data corresponding to the respective program states. The program states including first to eighth states PV0 to PV7 illustrate threshold voltage distribution of memory cells in the semiconductor memory device. During a read operation, each of the selected memory cells may be in any one state among the first state PV0 to the eighth state PV7.

First, the operation of reading the first page of the selected memory cells is performed at step S110 of FIG. 2. For this, a first read voltage RV11 for the operation of reading the first page is determined (at step S210). The first read voltage RV11 may be a predetermined value. The first read voltage RV11 is applied to the word lines coupled with the selected memory cells (at step S230). Depending on the threshold voltage values of the selected memory cells, data of the first page is read. That is, the values of first page data (i.e., P1) of memory cells corresponding to the first to fourth states PV0 to PV3 are “0” (i.e., “0” may indicate a logic low value or state), associated bits is transmitted to the corresponding page buffers. That is, the values of first page data (i.e., P1) of memory cells corresponding to the fifth to eighth states PV4 to PV7 are “1” (i.e., “1” may indicate a logic high value or state), associated bits are transmitted to the corresponding page buffers. At step S250, data transmitted to the page buffers PB1 to PBm is transmitted, as page read result data, to the page data storage unit 160. The operation of reading the first page of the selected memory cells is completed through steps S210 to S250 (at step S110). Subsequently, the operation of reading the second to N-th pages is performed through step S130.

At step S310, the control logic 140 refers to the page read result data PRD transmitted from the page data storage unit 160. At step S330, the control logic 140 selectively determines a read voltage for reading the second page based on the page read result data PRD. Referring to FIG. 5, the second page read voltage for reading the second page includes a second read voltage RV21 and a third read voltage RV22. The control logic 140 may select any one of the second read voltage RV21 and the third read voltage RV22 or both the second read voltage RV21 and the third read voltage RV22, based on the page read result data PRD.

In the case where all of the values of the first page data of the selected memory cells are “0” as the result of reading the first page, the program state of each of the selected memory cells corresponds to any one of the first state PV0 to the fourth state PV3, and there is no memory cell corresponding to any one of the fifth state PV4 to the eighth state PV7. In this case, there is no need to apply the third read voltage RV22, so that the control logic 140 selects only the second read voltage RV21. Thereafter, at step S350, only the second read voltage RV21 is applied to the word lines of the selected memory cells. Because each of the memory cells corresponds to any one of the first state PV0 to the fourth state PV3, the second page data of all of the selected memory cells may be read by applying only the second read voltage RV21.

In the case where all of the values of the first page data of the selected memory cells are “1” as the result of reading the first page, the program state of each of the selected memory cells corresponds to any one of the fifth state PV4 to the eighth state PV7, and there is no memory cell corresponding to any one of the first state PV0 to the fourth state PV3. In this case, there is no need to apply the second read voltage RV21, so that the control logic 140 selects only the third read voltage RV22. Thereafter, at step S350, only the third read voltage RV22 is applied to the word lines of the selected memory cells. Because each of the memory cells corresponds to any one of the fifth state PV4 to the eighth state PV7, the second page data of all of the selected memory cells can be read by applying only the third read voltage RV22.

In the case where both “0” and “1” are present in the first page data of the selected memory cells as a result of reading the data of the first page, it is impossible to read the second page data of the selected memory cells only using any one of the second read voltage RV21 and the third read voltage RV22. Therefore, in this case, the control logic 140 selects both the second read voltage RV21 and the third read voltage RV22. Thereafter, at step S350, the second read voltage RV21 and the third read voltage RV22 are sequentially applied, whereby the second page data of all of the selected memory cells can be read.

In an embodiment of the present disclosure, depending on the program states of the selected memory cells, less than two read voltage may be applied to read the second page. In this case, since the number of read voltages applied to read the data of the second page is reduced compared to the conventional case, the time it takes to perform the read operation may be reduced.

Although the description of the read operation for TLCs has been made in FIG. 5, the above description may be applied to that of a read operation for MLCs. Hereinbelow, an additional operation for reading data of a third page of TLCs will be described.

At step S370, the second page data read through step S350 is re-stored in the page data storage unit 160. The first page data and the second page data are transmitted, as the page read result data PRD, to the control logic 140. The control logic 140 selectively determines a read voltage for reading the third page data (i.e., P3) of the selected memory cells, based on the page read result data PRD including the first page data (i.e., P1) and the second page data (i.e., P2).

To read the third page, step S310 to step S370 may be repeatedly performed. At step S310 of reading the third page, the control logic 140 refers to the page read result data PRD stored in the page data storage unit 160. In this case, the page read result data PRD may include the first page data and the second page data. The control logic 140 may analyze threshold voltage distribution of the selected memory cells, based on the first page data and the second page data. Thereafter, depending on a result of the analysis, a read voltage for reading the data of the third page may be determined.

At step S330, the control logic 140 selectively determines the read voltage of the third page, based on the result of reading the first and second pages. Hereinbelow, a method of selecting the read voltage of the third page will be described by several examples. Referring to FIG. 5, the third page read voltage for reading the third page includes a fourth read voltage RV31, a fifth read voltage RV32, a sixth read voltage RV33 and a seventh read voltage RV34.

In an example, in the case where the program state of each of the selected memory cells corresponds to only the first state PV0 or the second state PV1, all of the values of the first page data of the selected memory cells are ‘0’, and all of the values of the second page data are also ‘0’. When the result of referring to the page read result data PRD is as described above, the control logic 140 selects only the fourth read voltage RV31 to read the data of the third page. Since the program state of each of the memory cells corresponds to only the first state PV0 or the second state PV1, the third page data of all of the selected memory cells may be read even if only the fourth read voltage RV31 is applied.

In another example, in the case where the program state of each of the selected memory cells corresponds to only the seventh state PV6 or the eighth state PV7, all of the values of the first page data of the selected memory cells are ‘1’, and all of the values of the second page data are ‘0’. When the result of referring to the page read result data PRD is as described above, the control logic 140 selects only the seventh read voltage RV34 to read the data of the third page. Since the program state of each of the memory cells corresponds to only the seventh state PV6 or the eighth state PV7, the third page data of all of the selected memory cells may be read even if only the seventh read voltage RV34 is applied.

In the same manner, in the case where all of the values of the first page data of the selected memory cells are ‘0’ and all of the values of the second page data are ‘1’ (the program state of each of the memory cells corresponds to only the third state PV2 or the fourth state PV3), the control logic 140 selects the fifth read voltage RV32. Furthermore, in the case where all of the values of the first page data of the selected memory cells are ‘1’ and all of the values of the second page data are ‘1’ (the program state of each of the memory cells corresponds to only the fifth state PV4 or the sixth state PV5), the control logic 140 selects the sixth read voltage RV33.

In the case where both “0” and “1” are present in the values of the first page data of the selected memory cells, the control logic 140 may select a read voltage depending on the value of the second page data. That is, in the case where both ‘0’ and ‘1’ are present in the values of the first page data and all of the values of the second page data are ‘0’, the program state of each of the selected memory cells corresponds to any one of the first state PV0, the second state PV1, the seventh state PV6 and the eighth state PV7. Therefore, in this case, the control logic 140 selects the fourth read voltage RV31 and the seventh read voltage RV34. In another example, in the case where both ‘0’ and ‘1’ are present in the values of the first page data and all of the values of the second page data are ‘1’, the program state of each of the selected memory cells corresponds to any one of the third state PV2, the fourth state PV3, the fifth state PV4 and the sixth state PV5. In this case, the control logic 140 selects the fifth read voltage RV32 and the sixth read voltage RV33.

In the case where both “0” and “1” are present in the values of the second page data of the selected memory cells, the control logic 140 may select a read voltage depending on the value of the first page data. That is, in the case where both ‘0’ and ‘1’ are present in the values of the second page data and all of the values of the first page data are ‘0’, the program state of each of the selected memory cells corresponds to any one of the first state PV0, the second state PV1, the third state PV2 and the fourth state PV4. In this case, the control logic 140 selects the fourth read voltage RV31 and the fifth read voltage RV32. In another example, in the case where both ‘0’ and ‘1’ are present in the values of the second page data and all of the values of the second page data are ‘1’, the program state of each of the selected memory cells corresponds to any one of the fifth state PV4, the sixth state PV5, the seventh state PV6 and the eighth state PV7. In this case, the control logic 140 selects the sixth read voltage RV33 and the seventh read voltage RV34.

Lastly, in the case where both ‘0’ and ‘1’ are present in the values of the first page data of the selected memory cells and both ‘0’ and ‘1’ are also present in the values of the second page data, the control logic 140 selects the fourth read voltage RV31, the fifth read voltage RV32, the sixth read voltage RV33 and the seventh read voltage RV34.

At step S350 of reading the third page, the determined read voltage is applied to read the page data of the selected memory cells. In an embodiment of the present disclosure, depending on the program states of the selected memory cells, less than four read voltage may be applied to read the third page. In this case, since the number of read voltages applied to read the data of the third page is reduced compared to the conventional case, the time it takes to perform the read operation may be reduced. Consequently, according to the present disclosure, the number of read voltages needed to read the data of the second and third pages may be reduced. Therefore, the time it takes to read data of the entire pages is reduced, so that the operation speed of the semiconductor memory device can be enhanced.

FIG. 6 is a diagram illustrating threshold voltage states of memory cells and read voltages corresponding thereto, for each of the memory cells that stores four-bit data. Referring to FIG. 6, there are illustrated program states of QLCs and values of 4-bit data corresponding to the respective program states. The program states including first to sixteenth states PV0 to PV15 illustrate threshold voltage distribution of memory cells in the semiconductor memory device. During a read operation, each of the selected memory cells may be in any one state among the first state PV0 to the sixteenth state PV15.

Even in the case of QLCs, a process of reading data of first to third pages may be performed in a manner similar to that of the case of TLCs described with reference to FIG. 5. In the case of QLCs, the corresponding process further includes the step of reading a fourth page. The fourth page data, for example, may be illustrated to correspond with ‘P4’ as illustrated in FIG. 6.

The control logic 140 determines a read voltage for reading the fourth page, based on page read result data PRD including the first to third page data (i.e., P1, P2, and P3). Referring to FIG. 6, the fourth page read voltage for reading the fourth page includes eighth to fifteenth read voltages RV41 to RV48.

In an example, in the case where all of the values of the first page data (i.e., P1) are ‘0’, all of the values of the second page data (i.e., P2) are ‘1’, and the values of the third page data (i.e., P3) have both ‘0’ and ‘1’, the program state of each of the selected memory cells corresponds to any one of the fifth state PV4 to the eighth state PV7. In this case, the control logic 140 selects the tenth read voltage RV43 and the eleventh read voltage RV44.

In an example, in the case where all of the values of the first page data are ‘1’, the values of the second page data have ‘0’ and ‘1’, and all of the values of the third page data are ‘0’, the program state of each of the selected memory cells corresponds to any one of the ninth state PV8, the tenth state PV9, the fifteenth state PV14 and the sixteenth state PV15. In this case, the control logic 140 selects the twelfth read voltage RV45 and the fifteenth read voltage RV48.

In an example, in the case where all of the values of the first page data are ‘0’, all of the values of the second page data are ‘0’, and all of the values of the third page data are ‘1’, the program state of each of the selected memory cells corresponds to any one of the third state PV2 and the fourth state PV3. In this case, the control logic 140 selects only the ninth read voltage RV42.

As such, depending on data distribution of the selected memory cells, the control logic selects one, four or eight read voltages. In the case where the control logic selects one or four read voltages to read data of the fourth page, the time required for the read operation is reduced, compared to that of the case which eight read voltages are applied. Therefore, the operation speed of the semiconductor memory device is enhanced.

Although not illustrated in FIGS. 5 and 6, not only may the read operation method according to an embodiment of the present disclosure be applied to a semiconductor memory device including memory cells each of which stores 2-bit data, but may also be applied to a semiconductor memory device including memory cells each of which stores 5- or more-bit data.

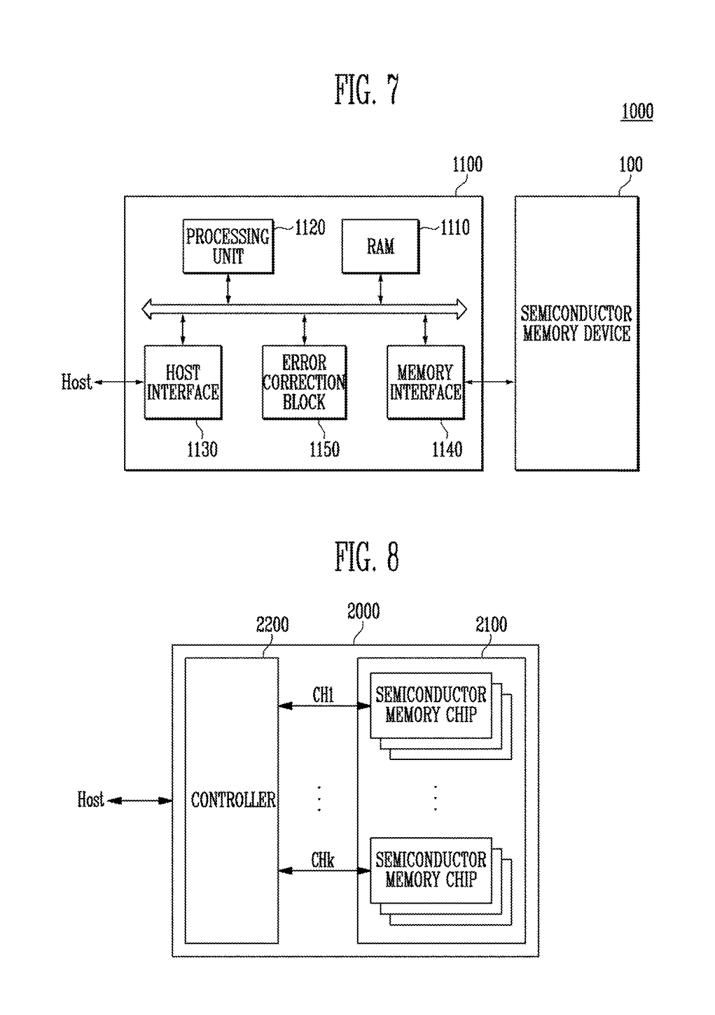

FIG. 7 is a block diagram illustrating a memory system including the semiconductor memory device of FIG. 1.

Referring to FIG. 7, the memory system 1000 includes the semiconductor memory device 100 and a controller 1100. The semiconductor memory device 100 may have the same configuration and operation as those of the semiconductor memory devices described with reference to FIG. 1. Hereinafter, repetitive explanations will be omitted.

The controller 1100 is coupled to a host Host and the semiconductor memory device 100. The controller 1100 is configured to access the semiconductor memory device 100 in response to a request from the host Host. For example, the controller 1100 is configured to control read, write, erase, and background operations of the semiconductor memory device 100. The controller 1100 is configured to provide an interface between the host Host and the semiconductor memory device 100. The controller 1100 is configured to drive firmware for controlling the semiconductor memory device 100.

The controller 1100 includes a RAM (Random Access Memory) 1110, a processing unit 1120, a host interface 1130, a memory interface 1140, and an error correction block 1150. The RAM 1110 is used as at least one of an operation memory of the processing unit 1120, a cache memory between the semiconductor memory device 100 and the host Host, and a buffer memory between the semiconductor memory device 100 and the host Host. The processing unit 1120 controls the overall operation of the controller 1100. In addition, the controller 1100 may temporarily store program data provided from the host Host during the write operation.

The host interface 1130 includes a protocol for performing data exchange between the host Host and the controller 1100. In an example of an embodiment, the controller 1100 is configured to communicate with the host Host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, and an integrated drive electronics (IDE) protocol, a private protocol, and the like.

The memory interface 1140 interfaces with the semiconductor memory device 100. For example, the memory interface includes a NAND interface or NOR interface.

The error correction block 1150 uses an error correcting code (ECC) to detect and correct an error in data received from the semiconductor memory device 100. The processing unit 1120 may adjust the read voltage according to an error detection result from the error correction block 1150, and control the semiconductor memory device 100 to perform re-reading. In an example of an embodiment, the error correction block may be provided as an element of the controller 1100.

The controller 1100 and the semiconductor memory device 100 may be integrated into a single semiconductor device. In an example of an embodiment, the controller 1100 and the semiconductor memory device 100 may be integrated into a single semiconductor device to form a memory card. For example, the controller 1100 and the semiconductor memory device 100 may be integrated into a single semiconductor device and form a memory card such as a personal computer memory card international association (PCMCIA), a compact flash card (CF), a smart media card (SM or SMC), a memory stick multimedia card (MMC, RS-MMC, or MMCmicro), a SD card (SD, miniSD, microSD, or SDHC), a universal flash storage (UFS), and the like.

The controller 1100 and the semiconductor memory device 100 may be integrated into a single semiconductor device to form a solid state drive (SSD). The SSD includes a storage device formed to store data in a semiconductor memory. When the memory system 1000 is used as the SSD, an operation speed of the host Host coupled to the memory system 1000 may be phenomenally improved.

In an embodiment, the memory system 1000 may be provided as one of various elements of an electronic device such as a computer, a ultra mobile PC (UMPC), a workstation, a net-book, a personal digital assistants (PDA), a portable computer, a web tablet, a wireless phone, a mobile phone, a smart phone, an e-book, a portable multimedia player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various devices for forming a home network, one of various electronic devices for forming a computer network, one of various electronic devices for forming a telematics network, an RFID device, one of various elements for forming a computing system, or the like.

In an example of an embodiment, the semiconductor memory device 100 or the memory system 1000 may be embedded in various types of packages. For example, the semiconductor memory device 100 or the memory system 1000 may be packaged in a type such as Package on Package (PoP), Ball grid arrays (BGAs), Chip scale packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), or the like.

FIG. 8 is a block diagram illustrating an example of application of the memory system of FIG. 7.

Referring to FIG. 8, the memory system 2000 includes a semiconductor memory device 2100 and a controller 2200. The semiconductor memory device 2100 includes a plurality of memory chips. The semiconductor memory chips are divided into a plurality of groups.

Referring to FIG. 8, it is illustrated that each of the plurality of groups communicates with the controller 2200 through a corresponding one of first to k-th channels CH1 to CHk. Each semiconductor memory chip may have the same configuration and operation as those of an embodiment of the semiconductor memory devices 100 described with reference to FIG. 1.

Each group communicates with the controller 2200 through one common channel. The controller 2200 has the same configuration as that of the controller 1100 described with reference to FIG. 7 and is configured to control a plurality of memory chips of the semiconductor memory device 2100 through the plurality of channels CH1 to CHk.

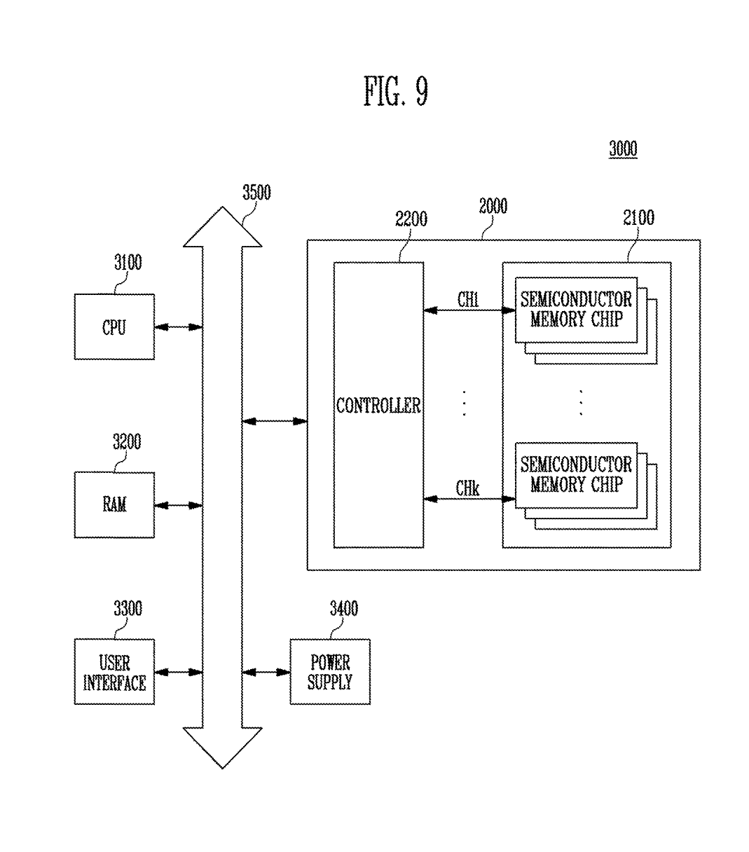

FIG. 9 is a block diagram illustrating a computing system including the memory system illustrated with reference to FIG. 8.

Referring to FIG. 9, the computing system 3000 may include a central processing unit (CPU) 3100, a RAM 3200, a user interface 3300, a power supply 3400, a system bus 3500, and a memory system 2000.

The memory system 2000 is electrically coupled to the CPU 3100, the RAM 3200, the user interface 3300, and the power supply 3400 through the system bus 3500. Data provided through the user interface 3300 or processed by the CPU 3100 is stored in the memory system 2000.

Referring to FIG. 9, the semiconductor memory device 2100 is illustrated as being coupled to the system bus 3500 through the controller 2200. However, the semiconductor memory device 2100 may be directly coupled to the system bus 3500. The function of the controller 2200 may be performed by the CPU 3100 and the RAM 3200.

Referring to FIG. 9, the memory system 2000 described with reference to FIG. 8 is illustrated as being used. However, the memory system 2000 may be replaced with the memory system 1000 described with reference to FIG. 7. In an embodiment, the computing system 3000 may include all of the memory systems 1000 and 2000 described with reference to FIGS. 7 and 8.

According to the present disclosure, an operation speed during a read operation of a semiconductor memory device may be enhanced.

Examples of embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A semiconductor memory device comprising:
a memory cell array including a plurality of memory cells each of which is configured to store two or more bits of data;
a peripheral circuit configured to read the data stored in the plurality of memory cells;
a control logic configured to control the peripheral circuit to perform a read operation for the memory cell array; and
a page data storage unit configured to store a read result of first page data of selected memory cells of the memory cell array,
wherein the first page data is read based on a first page read voltage, and
wherein the control logic selectively determines a second page read voltage for reading second page data of the selected memory cells, based on the read result of the first page data that is stored in the page data storage unit.

2. The semiconductor memory device according to claim 1,
wherein the first page read voltage includes a first read voltage,
wherein the second page read voltage includes a second read voltage and a third read voltage, and
wherein the control logic determines at least one of the second read voltage and the third read voltage as the second page read voltage, based on the read result of the first page data that is stored in the page data storage unit.

3. The semiconductor memory device according to claim 2,
wherein the second read voltage is a voltage for reading the second page data of memory cells that are in a state in which values of the first page data thereof are ‘0’,
wherein the third read voltage is a voltage for reading the second page data of memory cells that are in a state in which values of the first page data thereof are ‘1’, and
wherein ‘0’ indicates a logic low value and ‘1’ indicates a logic high value.

4. The semiconductor memory device according to claim 3, wherein when all of the values of the first page data stored in the page data storage unit are ‘0’, the control logic selects the second read voltage as the second page read voltage.

5. The semiconductor memory device according to claim 3, wherein when all of the values of the first page data stored in the page data storage unit are ‘1’, the control logic selects the third read voltage as the second page read voltage.

6. The semiconductor memory device according to claim 3, wherein when the values of the first page data stored in the page data storage unit are both ‘0’ and ‘1’, the control logic selects the second and third read voltages as the second page read voltage.

7. The semiconductor memory device according to claim 1, wherein the peripheral circuit comprises:
an address decoder coupled to the memory cell array through word lines; and
an read and write (read/write) circuit having a plurality of page buffers coupled to the memory cell array through bit lines, the page buffers being configured to sense threshold voltages of memory cells connected to a word line selected by the address decoder, to read data of the memory cells.

8. The semiconductor memory device according to claim 7, wherein the peripheral circuit further comprises:
a voltage generation unit generating the first page read voltage and the second page read voltage.

9. A method of operating a semiconductor memory device including a plurality of memory cells each of which is configured to store two or more bits of data, the method comprising:
reading first page data of selected memory cells; and
reading second to N-th page data based on the read first page data,
wherein N is an integer greater than or equal to 2.

10. The method according to claim 9, wherein the reading of the second to N-th page data comprises:
referring to a read result of previous page data of the selected memory cells; and
determining a page read voltage for reading corresponding page data, based on the read result of the previous page data, and
wherein the number of page read voltages is determined depending on the read result of the previous page data.

11. A method of operating a semiconductor memory device including a plurality of memory cells each of which is configured to store two or more bits of data, the method comprising:
reading, using a first read voltage for a first page read voltage, first page data of selected memory cells among the plurality of memory cells;
selectively determining a second page read voltage for reading second page data of the selected memory cells, based on a read result of the first page data; and
reading the second page data of the selected memory cells, based on the determined second page read voltage.

12. The method according to claim 11,
wherein the second page read voltage includes a second read voltage and a third read voltage,
wherein the second read voltage is a voltage for reading the second page data of memory cells that are in a state in which values of the first page data thereof are ‘0’,
wherein the third read voltage is a voltage for reading the second page data of memory cells that are in a state in which values of the first page data thereof are ‘1’, and
wherein ‘0’ indicates a logic low value and ‘1’ indicates a logic high value.

13. The method according to claim 12, wherein the selectively determining of the second page read voltage comprises:
determining the second read voltage as the second page read voltage when all of the values of the first page data are ‘0’ as the read result of the first page data.

14. The method according to claim 12, wherein the selectively determining of the second page read voltage comprises:
determining the third read voltage as the second page read voltage when all of the values of the first page data are ‘1’ as the read result of the first page data.

15. The method according to claim 12, wherein the selectively determining of the second page read voltage comprises:
determining the second and third read voltages as the second page read voltage when the values of the first page data include both ‘0’ and ‘1’ as the read result of the first page data.

16. The method according to claim 12, further comprising;
selectively determining a third page read voltage for reading third page data of the selected memory cells, based on the read result of the first page data and a read result of the second page data; and
reading the third page data of the selected memory cells, based on the determined third page read voltage.

17. The method according to claim 16,
wherein the third page read voltage includes a fourth read voltage to a seventh read voltage,
wherein the fourth read voltage is a voltage for reading the third page data of memory cells that are in a state in which values of the first and second page data thereof are ‘0’,
wherein the fifth read voltage is a voltage for reading the third page data of memory cells that are in a state in which the values of the first page data thereof are ‘0’ and the values of the second page data thereof are ‘1’,
wherein the sixth read voltage is a voltage for reading the third page data of memory cells that are in a state in which the values of the first and second page data thereof are ‘1’, and
wherein the seventh read voltage is a voltage for reading the third page data of memory cells that are in a state in which the values of the first page data thereof are ‘1’ and the values of the second page data thereof are ‘0’.

18. The method according to claim 16, wherein, depending on the read result of the first and second pages of the selected memory cells,
when the selected memory cells include memory cells of which the values of the first page data are ‘0’ and of which the values of the second page data are ‘0’, the fourth read voltage is included in the third page read voltage,
when the selected memory cells include memory cells of which the values of the first page data are ‘0’ and of which the values of the second page data are ‘1’, the fifth read voltage is included in the third page read voltage,
when the selected memory cells include memory cells of which the values of the first page data are ‘1’ and of which the values of the second page data are ‘1’, the sixth read voltage is included in the third page read voltage, and
when the selected memory cells include memory cells of which the values of the first page data are ‘1’ and of which the values of the second page data are ‘0’, the seventh read voltage is included in the third page read voltage.

19. The method according to claim 16, further comprising:
selectively determining a fourth page read voltage for reading fourth page data of the selected memory cells, based on a read result of the first to third page data; and
reading the fourth page data of the selected memory cells, based on the determined fourth page read voltage.
